(19) United States
(12) Patent Application Publication
(10) Pub. No.: US 2013/0167933 A1
(43) Pub. Date: Jul. 4, 2013

(54) INTRINSIC OXIDE BUFFER LAYERS FOR SOLAR CELLS

(71) Applicant: Syracuse University, Syracuse, NY (US)

(72) Inventor: Eric A. Schiff, Dewitt, NY (US)

(73) Assignee: SYRACUSE UNIVERSITY, Syracuse, NY (US)

(21) Appl. No.: 13/727,087

(22) Filed: Dec. 26, 2012

Related U.S. Application Data
(60) Provisional application No. 61/581,891, filed on Dec. 30, 2011.

(51) Int. Cl. H01L 31/0224

(52) U.S. Cl. CPC H01L 31/022483
USPC 136/265; 136/252

(57) ABSTRACT

A method of, and apparatus for, increasing the power output of the cell using one or more intrinsic oxide buffer layers to reduce extraneous optical absorption. The intrinsic oxide buffer layers can be, for example: (i) an undoped oxide film that is prepared without intentional doping, (ii) a compensated oxide layer that is prepared using compensating dopants to reduce the conductivity of the oxide film, which can be either undoped or doped, and/or (iii) a passivated oxide layer that is prepared using hydrogen or other atoms to improve the electronic properties of low conductivity oxide films.

### BACKGROUND OF THE INVENTION

1. Field of the Invention

The present invention relates to solar cells and, more specifically, to oxide buffer layer technology for use in solar cells.

2. Description of the Related Art

Solar cells have many layers of several types. One type is oxide layers that are transparent, but which also permit electrical currents to flow through them. In industrial practice, these oxide layers also have low electrical resistance; as one example, zinc oxide is commonly doped with about 1% of aluminum to make it less resistive. Typical conducting oxide materials have resistivities less than 10⁻³ Ω⁻¹ cm⁻¹. Commonly used oxide films include zinc oxide, tin oxide, indium-tin oxide alloys, and titanium oxide, among others.

These oxide layers can be used for several purposes in the cell. For example, they can be used to separate the reflecting metallic layer at the back of the cell from the semiconductor layer; in this application the layer must carry the “vertical,” top-to-bottom photocurrent of the cell from the semiconductor to the metal. Additionally, they can be used on the top of the cell; in this use, the layer must collect the vertical photocurrent from the cell and transfer it laterally to metallic wires. Many other uses are possible.

Such transparent conducting oxides (“TCOs”) suffer from a tradeoff: the less resistive the layer, the less transparent it is. Absorption of light by the TCO layers reduces the efficiency of a solar cell. In a thin-film silicon solar cell whose semiconductor layers total about 1 micron in thickness, it is estimated that this absorption reduces the power from the cell by more than 10%.

Accordingly, there is a continued need for methods, systems, and devices that increase the power output of a solar cell by, for example, reducing extraneous optical absorption.

### BRIEF SUMMARY OF THE INVENTION

It is therefore a principal object and advantage of the present invention to increase the power output of a solar cell.

It is another object and advantage of the present invention to increase the power output of a solar cell by reducing extraneous optical absorption.

It is yet another object and advantage of the present invention to increase the power output of a solar cell without significantly adding to the cost of the solar cell.

Other objects and advantages of the present invention will in part be obvious, and in part appear hereinafter.

In accordance with the foregoing objects and advantages, the present invention provides solar cells that increase the power output of the cell by reducing extraneous optical absorption. For example, the cells employ one or more intrinsic oxide buffer layers to improve the electrical power output of the solar cells; such intrinsic films will have resistivities greater, and possibly substantially greater, than the resistivity of 10⁻³ Ω⁻¹ cm⁻¹ or smaller that is typical of conducting oxide films. An intrinsic oxide buffer layer can mean, for example: (i) an undoped oxide film that is prepared without intentional doping, (ii) a compensated oxide layer that is prepared using compensating dopants to reduce the conductivity of the oxide film, which can be either undoped or doped, and/or (iii) a passivated oxide layer that is prepared using hydrogen or other atoms to improve the electronic properties of low conductivity oxide films.

### BRIEF DESCRIPTION OF THE SEVERAL VIEWS OF THE DRAWING(S)

The present invention will be more fully understood and appreciated by reading the following Detailed Description in conjunction with the accompanying drawings, in which:

FIG. 1 is a diagram of a solar cell illustrating the placement of an intrinsic oxide buffer (“IOB”) layer between the front TCO of the superstrate thin-film solar cell and the semiconductor layers; also envisioned are self-supporting solar cells that do not use superstrates or substrates.

FIG. 2 is a diagram of a substrate and a superstrate solar cell illustrating the placement of an IOB layer between the semiconductor layers and the backreflector of the solar cells; also envisioned are self-supporting solar cells that do not use a substrate or a superstrate.

FIG. 3 is a diagram of a solar cell illustrating the placement of an IOB layer between the semiconductor layers and a back TCO of a substrate solar cell; also envisioned are self-supporting solar cells that do not use a substrate.

FIG. 4 is a graph of the absorption coefficient spectra for crystalline silicon and for Al-doped ZnO.

FIG. 5 is a graph of the spatial profile of the square of the electric field amplitude is graphed for a high-order waveguide mode (vacuum wavelength=900 nm) in a thin-film solar cell.

FIG. 6 is a graph of higher order waveguide modes, where the mode energy spreads into the oxide and the glass.

FIG. 7 is a graph of the fraction of the total energy dissipation for each mode that occurs in the oxide.

FIG. 8 is a graph of the absorptance spectra for the simplified solar cell assuming a perfect anti-reflection coating.

### DETAILED DESCRIPTION OF THE INVENTION

Described herein is the use of ‘intrinsic’ oxide buffer layers to improve the electrical power output of solar cells. The term intrinsic applies to, for example: (i) ‘undoped’ oxide films that are prepared without intentional doping, (ii) ‘compensated’ oxide layers that are prepared using compensating dopants to reduce the conductivity of the oxide film, which can be either undoped or doped, and (iii) passivated oxide layers that are prepared using hydrogen or other atoms to improve the electronic properties of low conductivity oxide films. One beneficial use of these films is that intrinsic films are typically more transparent than more conducting oxide (“TCO”) films. While “intrinsic” generally refers to non-conducting layers, the use of nearly intrinsic layers, such as those have ten times reduced conductivity, may be acceptable for use in the present invention.

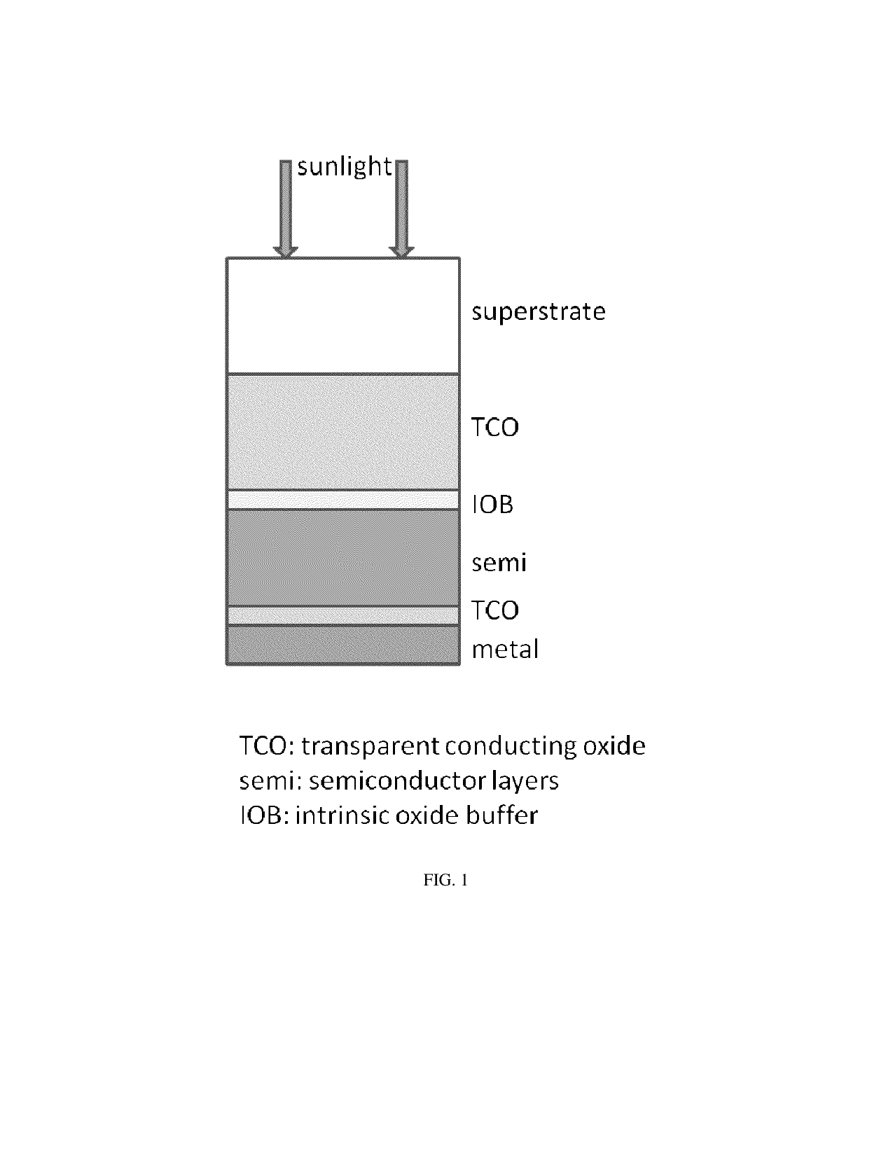

Referring now to the drawings, wherein like reference numerals refer to like parts throughout, there is seen in FIG. 1 a representative solar cell device 10 according to one embodiment in which an intrinsic oxide buffer layer 12 (denoted in all figures as “IOB”) is deposited between, for example, the uppermost semiconductor layer 14 of solar cell 10 and a conventional TCO layer 16. This use reduces the extraneous absorption of light by TCO 16, and thereby increases its absorption by the semiconductor; the interfaces are typically textured to enhance light-trapping effects. Increased semiconductor absorption will lead to increased power generation by the cell, as long as the electrical properties of the oxide layer are adequate. As further seen in FIG. 1, device 10 may further includes a second TCO layer 18 adjacent to semiconducting layer 14 and a metal layer 20 adjacent to second TCO layer 18, and a superstrate 22 positioned on conventional TCO layer 16 through which light would shine. Also envisioned are solar cells that do not use superstrates because they are self-supporting, such as monocrystalline or multicrystalline silicon solar cells. It should also be recognized by those of skill in the art that the semiconductor layer may consist of multiple layers, and typically needs at least two layers or sub-layers. For example, a silicon solar cell typically is a p-n structure, where n and p refer to n-type and p-type compositions. The layers may be created either by separate depositions, or by modifying a single layer to create an n-p interface inside it. Single-junction, thin-film silicon solar cells usually have three separately deposited layers p-i-n, where i refers to “intrinsic.” Multijunction solar cells may have 9 or more layers: p-i-n-p-i-n-p-i-n.

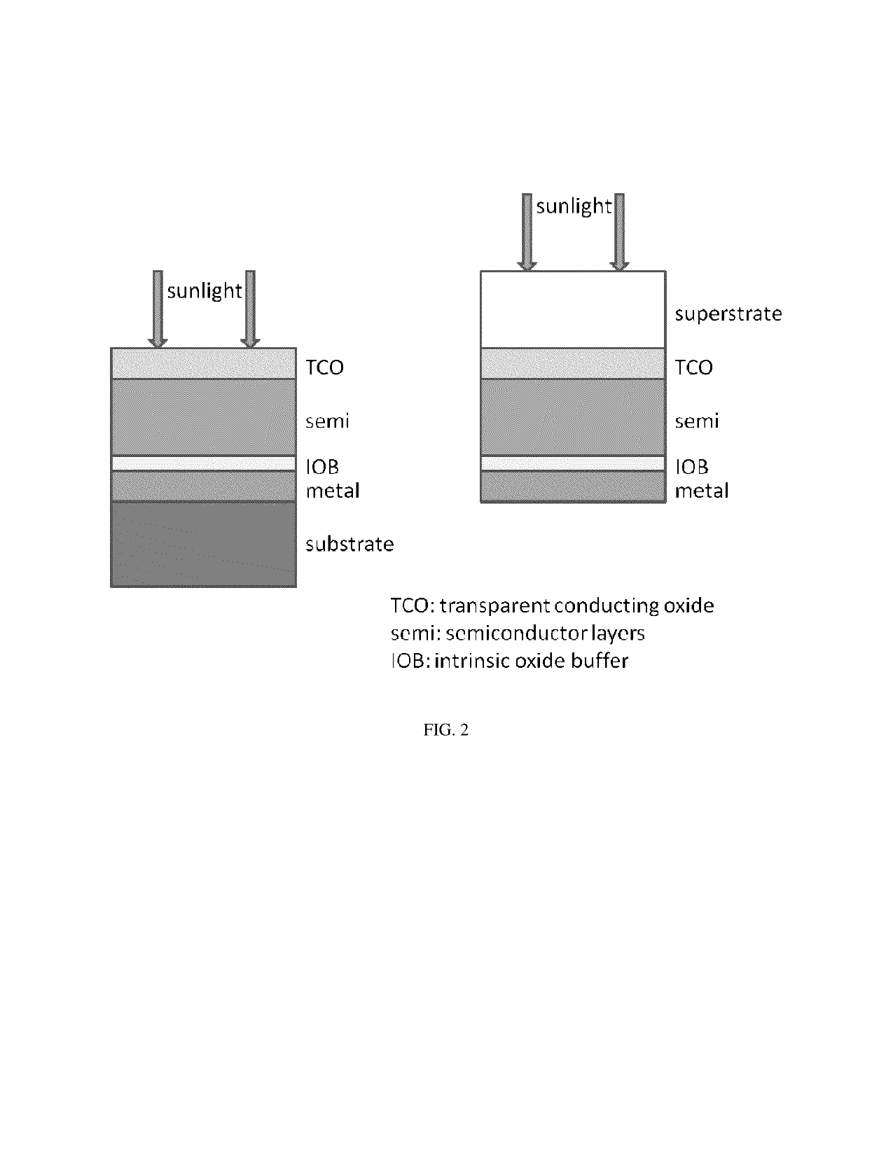

There are shown in FIG. 2 representative devices 30 according to one embodiment in which an intrinsic oxide buffer layer 32 is deposited between, for example, a bottommost semiconductor layer 34 and a metallic reflecting layer 36. A TCO layer 38 may be positioned on said semiconductor layer 34, and a substrate 40 positioned under the metal layer 36 (or a superstrate 42 positioned on TCO layer 38 as seen in the right hand embodiment). Alternatively, the semiconducting layer 34 may be self-supporting to avoid the need for a substrate or superstrate. Notably, these oxide layers 32 can be undoped, and either intrinsic or doped oxide buffer buffers can reduce extraneous optical absorption by the metallic layer. Intrinsic oxide buffer films would decrease extraneous absorption in the oxide film.

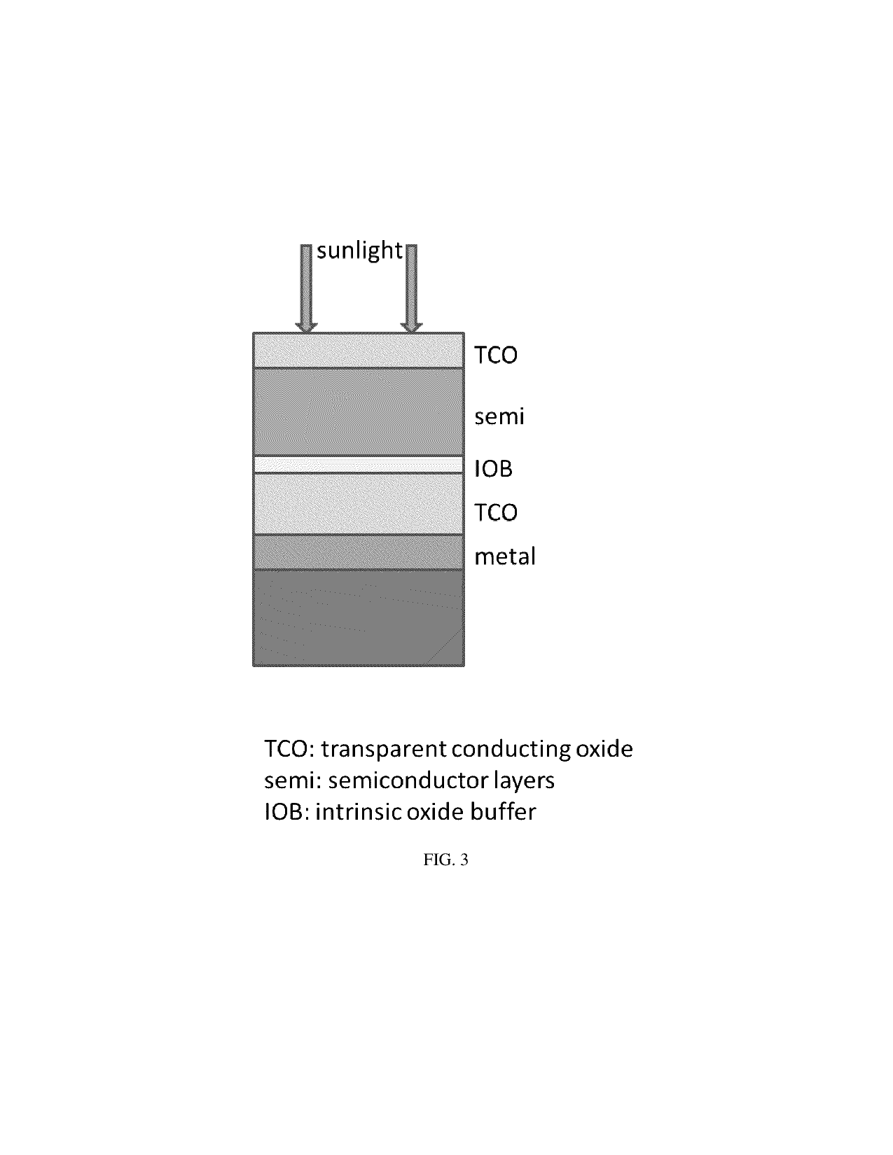

In yet another embodiment (not shown), the intrinsic oxide buffer layer is deposited between the bottommost semiconductor layer and a bottom TCO layer; such bottom TCOs can be used to created a textured interface. One of skill in the art would recognize that other embodiments in addition to the embodiments described above are possible, including the embodiment shown in FIG. 3 in which a device 50 includes an intrinsic oxide buffer layer 52 layer is placed between a semiconductor layer 54 having a front TCO layer 56 and a back TCO layer 58 positioned on a metal layer 60.

One benefit of incorporating such an intrinsic oxide buffer layer will also be realized when the interfaces between the layers of the solar cell are textured, as is commonly done to increase the trapping of sunlight in solar cells. For intrinsic oxide buffer layers, there will be an optimum thickness that represents a tradeoff between reduced optical absorption by the layer and degraded electrical properties of a cell. Preliminary calculations indicate that a 100 nm intrinsic zinc oxide film used at both the bottom and top of a cell could improve the power output of a 2.5 micron thin-film silicon solar cell from about 100 W/m² (the current best value) to 110-120 W/m². An increase is similarly anticipated for “multijunction” solar cells. Accordingly, these calculations indicate that the use of one or more intrinsic oxide buffer layers could increase the power output of a thin-film silicon solar cells by more than 10%. Importantly, the technology is not expected to add significantly to the cost of a cell and thus has the potential to reduce the installed cost of a cell by the same percentage as the increase in the power output.

Although the preliminary calculations were performed using a 100 nm intrinsic zinc oxide film used at both the bottom and top of a cell, many other thicknesses are possible, including substantially thicker or thinner than 100 nm. In addition to uniform layers, multiple layers in a single cell can be the same or varying thicknesses, with a first layer being a first thickness, a second layer being a second thickness, and so forth.

Yet another embodiment relates to introduce passivating atoms such as hydrogen to improve intrinsic oxide buffer layers. The type of charge transport that is envisioned for intrinsic oxide buffer layers is known as “space-charge limited current.” Intrinsic oxide films deposited using some traditional technologies may have defects in sufficient density such that the current injected into the film will not flow readily; one criterion is that a photocurrent of order 30-40 mA/cm²should flow through the intrinsic oxide buffer with a thickness of order 100 nm with a voltage less than 10 mV. To achieve this performance, excess defects may be passivated by introducing hydrogen during fabrication, by exposing the finished ZnO film to a hydrogen plasma, or by introducing atomic hydrogen to the films produced by other processes. It is known that the introduction of compensating atoms into undoped or doped oxide films reduces the conductivity and increases the transparency of the film. Nitrogen atoms have been introduced to reduce the conductivity of undoped ZnO films, and oxygen atoms have been introduced during sputtering of aluminum doped ZnO films to reduce conductivity. It has been shown that introducing compensating atoms also increases the transparency of the film. However, it is also within the scope of the present invention to introduce hydrogen to improve the electrical performance of intrinsic oxide buffer films beyond what can be obtained using compensating atoms such as oxygen or nitrogen.

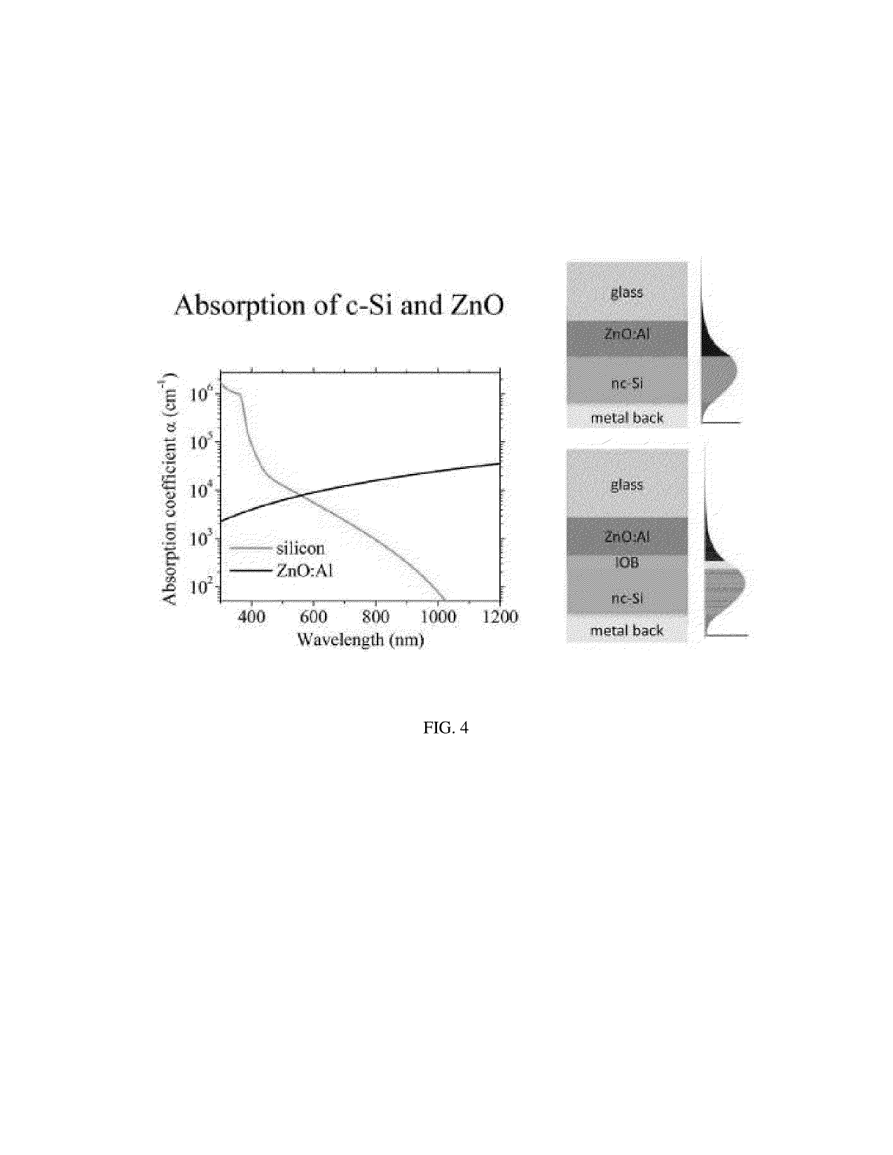

FIG. 4 illustrates the absorption coefficient spectra for crystalline silicon (nc-Si) and for Al-doped ZnO. Note that silicon absorbs much more strongly than the ZnO for wavelengths shorter than about 600 nm, but that doped ZnO absorbs more strongly at longer wavelengths. The actual absorption of light must be calculated for a specific device structure.

A simplified nanocrystalline silicon (nc-Si) solar cell structure without the intrinsic oxide buffer is illustrated in cross-section at the top right of FIG. 4. The nc-Si layer is 1.0 um thick; the ZnO:Al layer is 800 nm thick. The glass “superstrate” is thicker and is not shown to scale. Doped semiconductor layers and the oxide layer between the nc-Si and the metal back are not illustrated. Sunlight is incident from the top, through the glass. Most of the sunlight reaches the interface between the aluminum-doped zinc oxide layer (a typical transparent conducting oxide) and the nc-Si layer. At this point the textured interface couples the incident beam into the many possible electromagnetic modes of this system. Most of these modes are “waveguide modes” representing light that travels along the layers (and perpendicular to the plane of the diagram). The distribution of the electromagnetic energy in the simplest waveguide mode is illustrated at a wavelength of about 1000 nm. The mode's energy is being absorbed in the nc-Si film, which generates photocurrent, and also in the TCO, which does not generate photocurrent and is a parasitic loss. The lower diagram of FIG. 4 illustrates the effect of introducing an intrinsic oxide buffer (IOB), which has a much lower absorption coefficient. The IOB thus reduces the rate of energy loss to the ZnO:Al. Detailed calculations illustrated on the next pages show that this reduction benefits the efficiency of the solar cell.

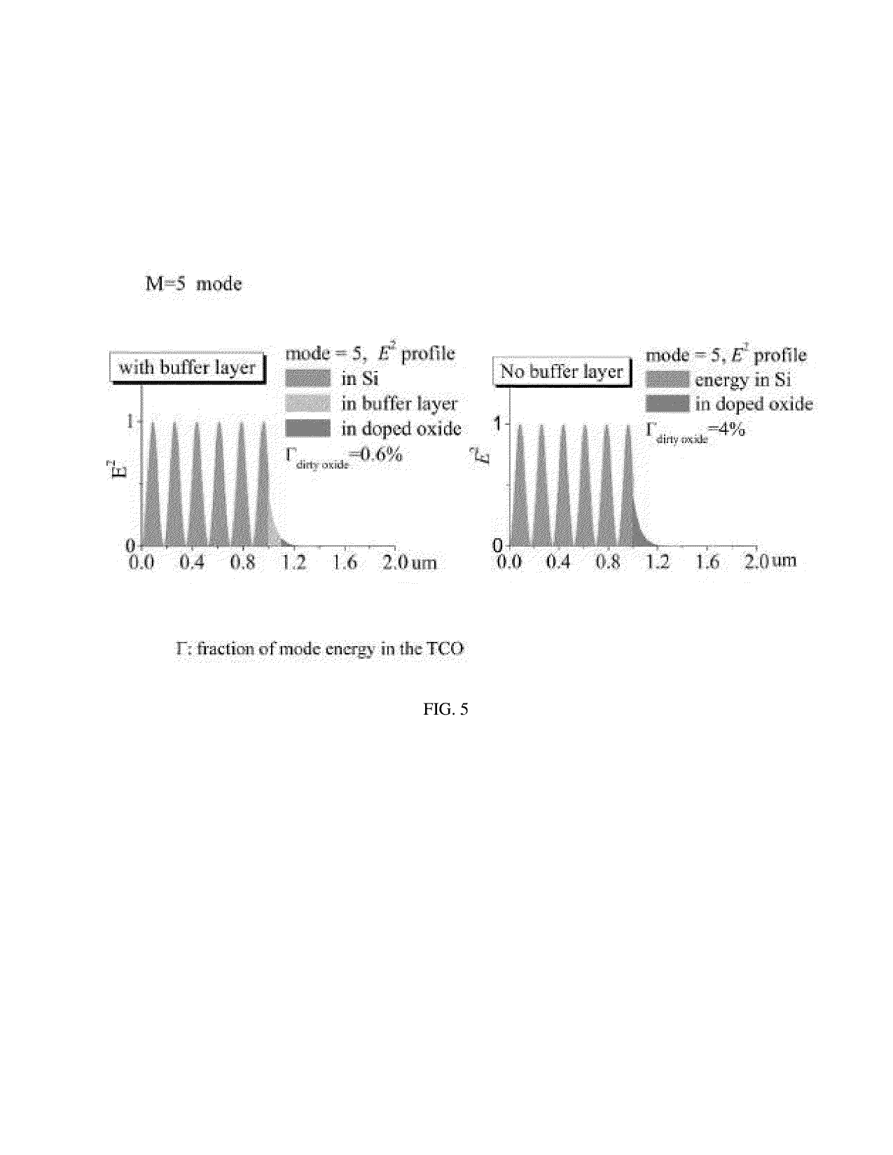

FIG. 5 shows the spatial profile of the square of the electric field amplitude is graphed for a high-order waveguide mode (vacuum wavelength=900 nm). 4% of the electromagnetic energy is in the TCO layer for this mode. The fraction of the electromagnetic energy in the doped oxide (the ZnO:Al from FIG. 4) falls to 0.6% after introduction of the intrinsic oxide buffer.

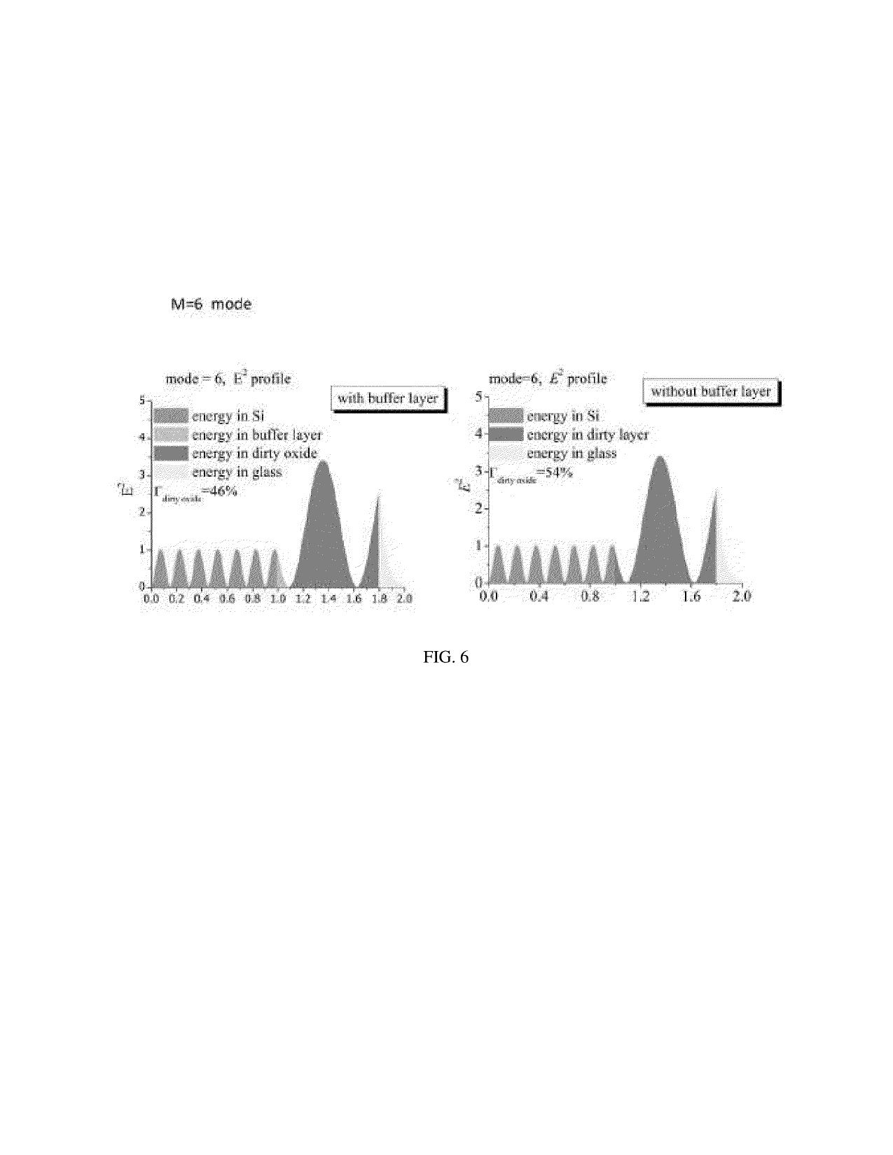

FIG. 6 shows that, for still higher order waveguide modes, the mode energy spreads into the oxide and the glass. Without the IOB layer, 54% of the mode energy is in the “dirty” oxide (ZnO:Al from the first slide). With the IOB layer, the fraction is reduced to 46%.

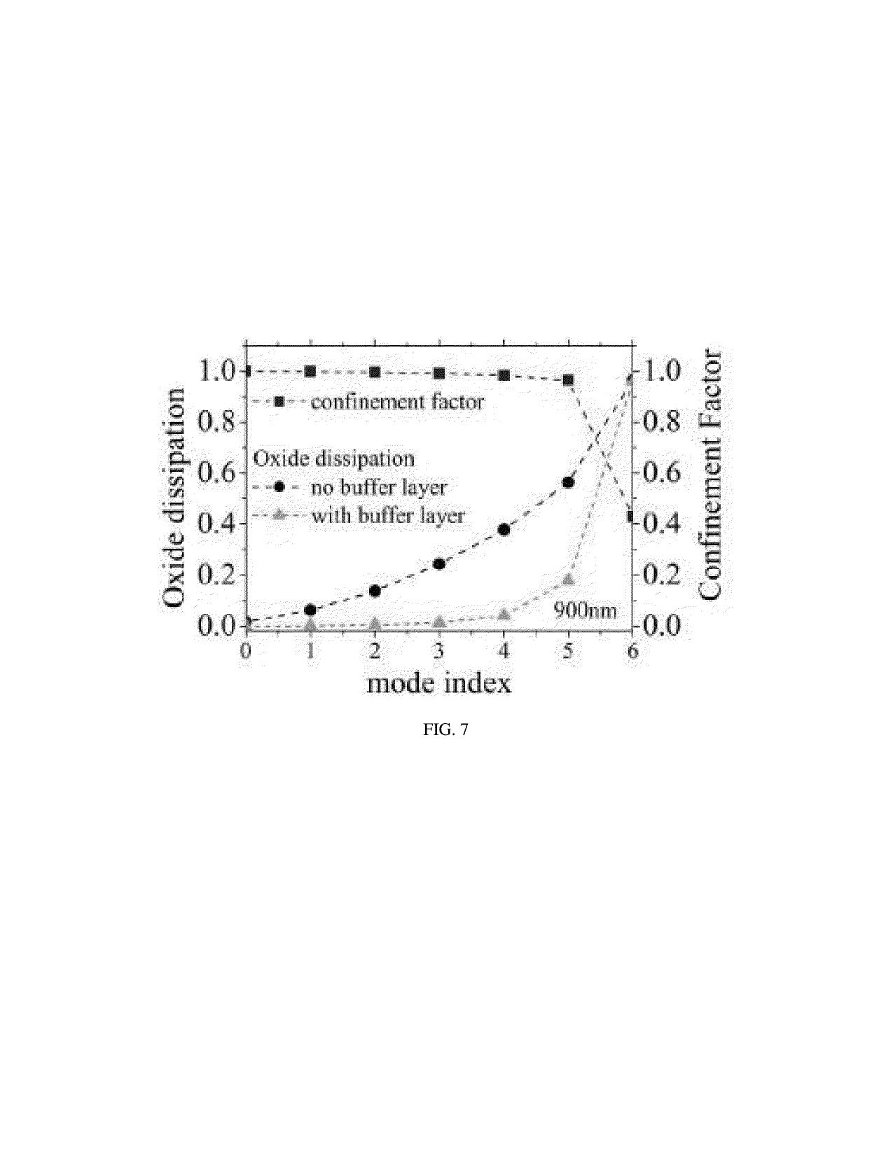

FIG. 7 illustrates the fraction of the total energy dissipation for each mode that occurs in the oxide. Only the fraction that is dissipated in the silicon contributes to the solar cell's power output.

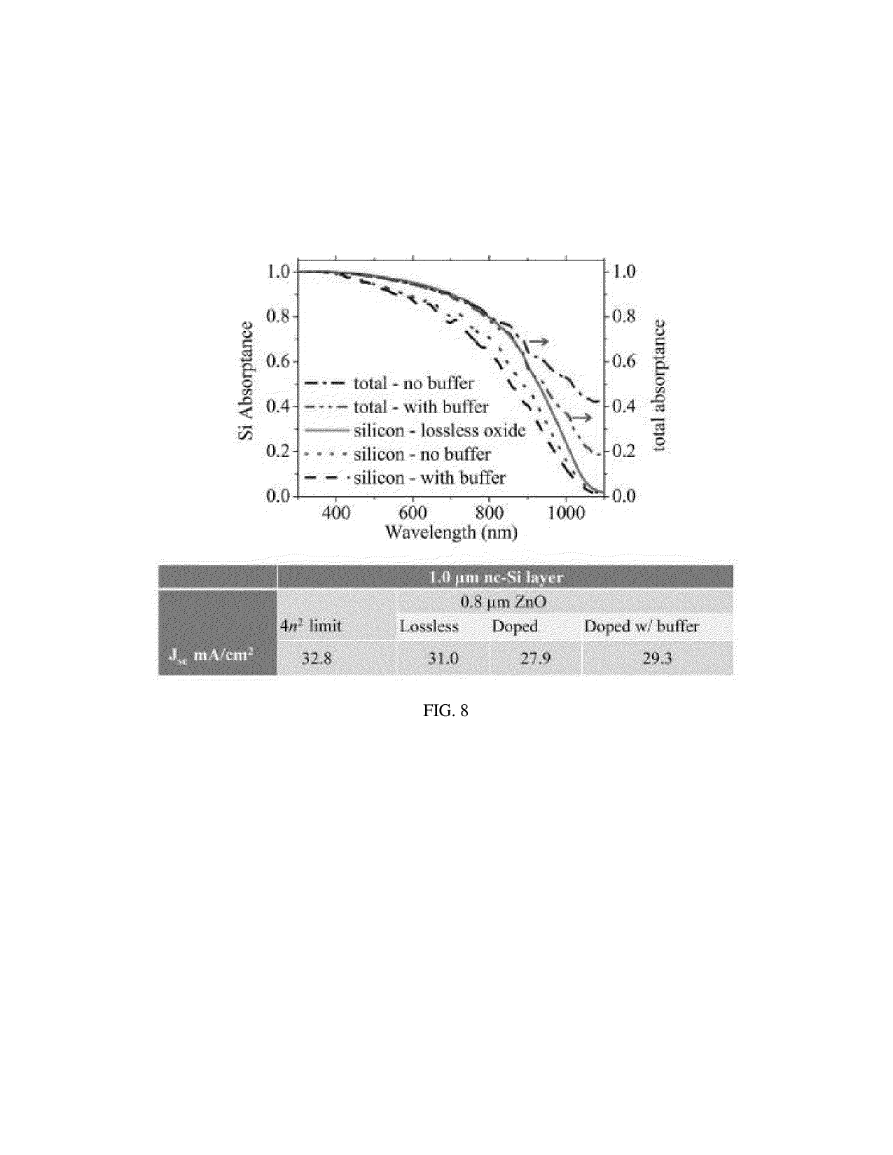

FIG. 8 displays the absorptance spectra for the simplified solar cell assuming a perfect anti-reflection coating. The total absorptance is the sum of absorptance in the silicon and in the ZnO:Al oxide; energy that is not absorbed is reflected from the structure. These results are calculated by summing the absorptance for each mode based on the assumption that all modes have the same stored energy in sunlight (the “ergodic” approximation). The calculations are shown with and without the intrinsic oxide buffer. As can be seen, the buffer reduces the total absorptance, and increases the silicon absorptance. For reference, the absorptance of a cell for which the oxide has no absorption is also shown (“ergodic limit”). Real cells need the oxide to be conducting, which requires that they have some absorption.

The table shows the photocurrent densities Jsc based on integrating the product of the solar photon flux, the silicon absorptance, and the electron charge. The 4n² limit is a well-known approximation for an ideal solar cell with a given thickness of semiconductor. The cell with a lossless oxide yields less current than does the 4n² calculation; this reflects the true mode density and the spreading of the mode energy to the oxide. Introducing a doped, conducting oxide drops the cell's photocurrent density by about 10% compared to the lossless case. Introducing the 100 nm intrinsic oxide buffer restores about half of this lost current, increasing the cell's power about 5%. The calculation is based on those in “Thermodynamic limit to photonic-plasmonic light trapping in thin films on metals”, E. A. Schiff, Journal of Applied Physics 110, 104501 (2011).

Although the present invention has been described in connection with a preferred embodiment, it should be understood that modifications, alterations, and additions can be made to the invention without departing from the scope of the invention as defined by the claims.

What is claimed is:

1. A solar cell, comprising:
a semi-conducting layer;
a transparent conducting oxide layer; and
an intrinsic oxide buffer layer positioned between said semi-conducting layer and said conducting oxide layer and adjacently thereto.

2. The solar cell of claim 1, further comprising a second transparent conducting oxide layer positioned adjacently to said semi-conducting layer on an opposing side from said intrinsic oxide buffer layer.

3. The solar cell of claim 2, a metal layer positioned adjacently to said second transparent conducting oxide layer.

4. The solar cell of claim 3, further comprising a superstrate positioned adjacently to said first transparent conducting oxide layer.

5. The solar cell of claim 2, further comprising a metal layer positioned adjacently to said first transparent conducting oxide layer.

6. The solar cell of claim 5, further comprising a substrate positioned adjacently to said metal layer on an opposing side from said first transparent conducting oxide layer.

7. The solar cell of claim 1, wherein said intrinsic oxide buffer layer comprises a compound selected from the group consisting of an undoped oxide, a compensated oxide having compensating dopants to reduce conductivity of said compensated oxide, a passivated oxide having a compound therein which improves electronic properties.

8. The solar cell of claim 7, wherein said compound comprises hydrogen.

9. The solar cell of claim 1, wherein said intrinsic oxide buffer layer is greater than 50 nanometers in thickness.

10. The solar cell of claim 1, further comprising a metal layer positioned adjacently to said transparent conducting oxide layer.

11. The solar cell of claim 1, wherein said intrinsic oxide buffer layer comprises zinc oxide compensated with hydrogen.

12. A solar cell, comprising:
a semi-conducting layer;
a metal layer; and
an intrinsic oxide buffer layer positioned between said semi-conducting layer and said metal layer and adjacent thereto.

13. The solar cell of claim 12, further comprising a substrate positioned adjacently to said metal layer on an opposing side from said intrinsic oxide buffer layer.

14. The solar cell of claim 13, further comprising a transparent conducting oxide layer positioned adjacently to said semi-conducting layer and said intrinsic oxide buffer layer.

15. The solar cell of claim 12, further comprising a superstrate positioned adjacently to said transparent conducting oxide layer on an opposing side from said semi-conducting layer.

16. The solar cell of claim 12, wherein said intrinsic oxide buffer layer is greater than 50 nanometers in thickness.

17. The solar cell of claim 12, wherein said intrinsic oxide buffer layer comprises zinc oxide compensated with hydrogen.
